(19) United States
(12) Patent Application Publication
(10) Pub. No.: US 2008/0316601 A1
(43) Pub. Date: Dec. 25, 2008

(54) Method for Manufacturing a Hybrid Microlens

(76) Inventors: Chul Jin Hwang, Gyeonggi-do (KR); Jong Sun Kim, Gyeonggi-do (KR); Young Bae Ko, Seoul (KR); Young Moo Heo, Seoul (KR)

Correspondence Address: KED & ASSOCIATES, LLP, P.O. Box 221200, Chantilly, VA, 20153-1200, US

(21) Appl. No.: 11/911,392

(22) PCT Filed: Mar. 6, 2006
(86) PCT No.: PCT/KR2006/000758

§ 371 Date: Oct. 12, 2007

(30) Foreign Application Priority Data
Apr. 15, 2005 (KR) 10-2005-0031604

(51) Int. Cl. G02B 27/12; G02B 5/02; G03F 7/20

(52) U.S. Cl. 359/599; 359/628; 430/321

(57) ABSTRACT

The present invention provides a method for manufacturing hybrid microlenses of a light guiding plate using a semiconductor reflow process, comprising: a first step of aligning a mask on a substrate coated with a photoresist, wherein the mask is formed with a first region through which light can be transmitted and a plurality of second regions through which light cannot be transmitted, and the second regions have different sizes and shapes to form hybrid arrays; a second step of performing slant light exposure and vertical light exposure at least once in such a manner that light radiated from the top to the bottom of the second regions forming the hybrid arrays has an unsymmetrical inclination angle in at least one direction; a third step of developing the slant light-exposed substrate to obtain hybrid photoresist posts with various sizes and shapes; a fourth step of performing a reflow process to allow the hybrid photoresist posts to be curved so that a hybrid microlens pattern can be obtained; a fifth step of fabricating a depressed stamper with the hybrid microlens pattern engraved in a depressed fashion therein; and a sixth step of forming a light guiding plate by using the depressed stamper as a mold so that the hybrid microlens pattern can be formed in a raised pattern in the light guiding plate.

### TECHNICAL FIELD

The present invention relates to a micro-pattern machining technology and a micro-molding technology, and more particularly, to a method for manufacturing hybrid microlenses for controlling light diffusion and dispersion and a viewing angle in a microlens array, a light guiding plate or the like, and a light guiding plate manufactured using the method.

### BACKGROUND ART

In general, a backlight unit of a liquid crystal display (LCD) is used as an illumination device that provides light uniformly over an entire panel of the liquid crystal display, and the panel of the liquid crystal display properly controls the amount of light to be transmitted so that an image can be displayed thereon. Contrary to CRTs, PDPs and FEDs, a liquid crystal display is a non-luminescent device and thus cannot be used in a dark place without light.

To solve such a disadvantage and allow a liquid crystal display to be used in a dark place, a backlight unit is used as an illumination device that provides light uniformly over an entire panel of the liquid crystal display.

The backlight unit comprises background light sources, a reflection plate for reflecting light, a light guiding plate, a diffusion plate, and the like. The light guiding plate functions to uniformly radiate light, which is emitted from the background light sources used as light sources at both lateral sides thereof, onto the entire face of the liquid crystal display.

For example, a conventional light guiding plate used in a mobile phone includes microlenses arranged in one direction on a rear face thereof, which are manufactured in the form of etched dots or diffusive ink dots with a predetermined size. However, the etched dot type has a problem in a wet etching process. Thus, there are problems in that it is difficult to manufacture a pattern with a certain size or distance, it is difficult to optically control light due to an uneven etched surface, production time is extended and production costs increase.

In addition, even in the case of the diffusive ink dot type, an optical efficiency is significantly degraded due to absorption and scattering of a diffusive ink itself. Furthermore, the liquid crystal display optically requires light with a larger emergence angle such as about 90 degrees with respect to the surface of the display. In a conventional light guiding plate, however, the emergence angle of light emerging from the light guiding plate is very small on the order of about 30 degrees with the face of the light guiding plate. Thus, there is a problem in that an expensive prism film or diffusion film should be used to increase the emergence angle.

In order to eliminate a film to be used, various patterns have been used. However, there is a problem in that since this pattern is formed through a mechanical process or an etching process, a uniform configuration cannot be easily achieved.

### DISCLOSURE OF INVENTION

### Technical Problem

An object of the present invention for solving the aforementioned problems is to provide a method for manufacturing hybrid microlenses of a light guiding plate using a reflow process and a light guiding plate manufactured using the method, wherein in order to replace a diffusive ink dot pattern or an etched dot pattern used for a conventional light guiding plate, hybrid microlenses comprising a light diffusion portion for diffusing light from a light input section by reflecting and refracting the light by means of a plurality of trapezoidal microlens on the order of micron and a light guiding portion for performing diffuse reflection of the light by means of hemispherical microlens to exhibit uniform luminance can be easily and simply manufactured so that the sizes or locations of the hybrid microlenses on a light guiding plate can be easily controlled according to a user's intention.

Further, another object of the present invention is to provide a method for manufacturing hybrid microlenses of a light guiding plate using a reflow process and a light guiding plate manufactured using the method, wherein the hybrid microlenses are manufactured to have rectangular shapes at the bottom and unsymmetrical rectangular post shapes at the tops thereof in a light diffusion portion, and circular shapes at the bottoms and hemispherical shapes at the tops thereof in a light guiding portion.

### Technical Solution

According to the present invention for achieving the objects, there is provided a method for manufacturing hybrid microlenses of a light guiding plate using a semiconductor reflow process, comprising: a first step of aligning a mask on a substrate coated with a photoresist, wherein the mask is formed with a first region through which light can be transmitted and a plurality of second regions through which light cannot be transmitted, and the second regions have different sizes and shapes to form hybrid arrays; a second step of performing slant light exposure and vertical light exposure at least once in such a manner that light radiated from the top to the bottom of the second regions forming the hybrid arrays has an unsymmetrical inclination angle in at least one direction; a third step of developing the slant light-exposed substrate to obtain hybrid photoresist posts with various sizes and shapes; a fourth step of performing a reflow process to allow the hybrid photoresist posts to be curved so that a hybrid microlens pattern can be obtained; a fifth step of fabricating a depressed stamper with the hybrid microlens pattern engraved in a depressed fashion therein; and a sixth step of forming a light guiding plate by using the depressed stamper as a mold so that the hybrid microlens pattern can be formed in a raised pattern in the light guiding plate.

### Advantageous Effects

As described above, according to the present invention, hybrid microlenses can be manufactured with photoresists formed by means of vertical light exposure and slant light exposure through a reflow process. Thus, there are advantages in that a hybrid microlens array pattern can be manufactured through a simplified manufacturing process and production costs and time can be reduced.

In addition, the sizes and inclinations of photoresists can be controlled through light-exposing and reflow processes so that hybrid microlenses can be arbitrarily manufactured according to manufacturer's intention. Thus, there is an advantage in that hybrid microlenses with desired optical properties can be arbitrarily fabricated on a light guiding plate.

### BRIEF DESCRIPTION OF THE DRAWINGS

FIG. 1 is a perspective view of a mask for use in the present invention.

FIGS. 2 to 4 show light-exposing procedures for fabricating unsymmetrical rectangular post-shaped photoresists according to an embodiment of the present invention.

FIGS. 5 and 6 are sectional views showing features of the sizes and shapes of the unsymmetrical rectangular post-shaped photoresists fabricated according to the embodiment of the present invention.

FIGS. 7, 8, 9 and 10 show the shapes of the photoresists changed into hybrid microlenses after a reflow process according to the embodiment of the present invention.

FIGS. 11 and 12 are views showing a process of fabricating a stamper according to an embodiment of the present invention.

FIG. 13 is a schematic view showing a process of fabricating a raised stamper according to an embodiment of the present invention.

### *DESCRIPTION OF REFERENCE NUMERALS FOR MAIN PARTS IN DRAWINGS*

21: Mask 22: First region
23: Hybrid array of second region 31: Substrate
32: PR (Photoresist) 34: Hybrid PR posts
36: Hybrid microlens pattern 41: Metallic thin film
42: Depressed stamper 44: Raised stamper

### BEST MODE FOR CARRYING OUT THE INVENTION

Hereinafter, preferred embodiments of the present invention will be described in detail with reference to the accompanying drawings.

In the following description, detailed explanation of known related functions and constitutions may be omitted to avoid unnecessarily obscuring the subject manner of the present invention.

Further, the terms used in the description are defined considering the functions of the present invention and may vary depending on the intention or usual practice of a user or operator. Therefore, the definitions should be made based on the entire contents of the description.

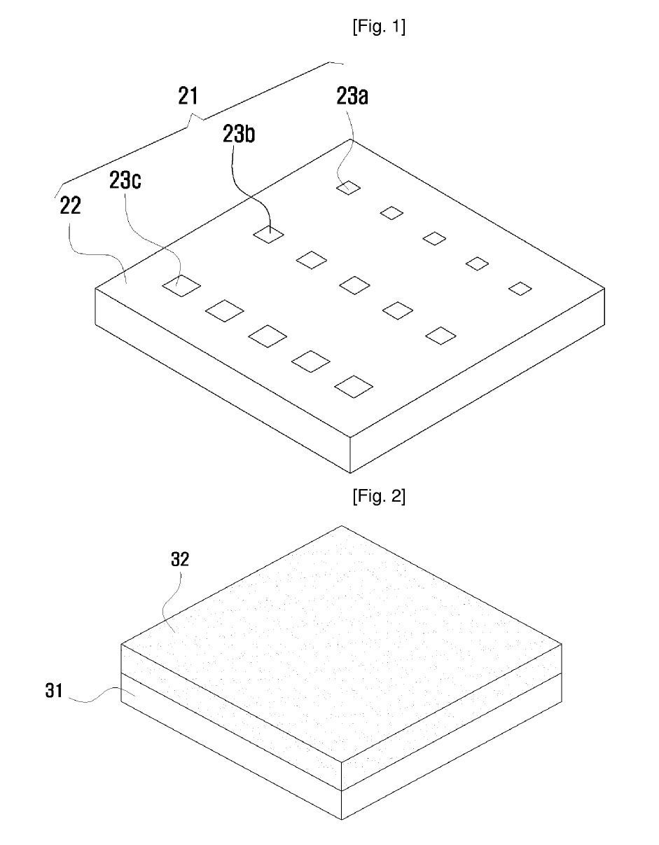

In the present invention, a mask 21 to be used for a light-exposing process is first fabricated, as shown in FIG. 1. Here, as for the mask, a film mask or a chromium mask may be used depending on the precision of a pattern. In case of the use of a chromium mask, the mask can be fabricated with a precision of about 1 [symbol] .

FIG. 1 is a perspective view of a mask for use in the present invention. As shown in this figure, the mask 21 comprises a first region 22 through which light can be transmitted, and a plurality of second regions 23a, 23b and 23c through which light cannot be transmitted. The second regions 23a, 23b and 23c have different sizes and shapes to constitute hybrid arrays 23.

Here, each of the second regions 23a, 23b and 23c is preferably formed in a rectangular shape but may be formed in other shapes such as a circle, ellipse, pentagon, hexagon, or the like.

In addition, the mask of the present invention may be formed such that the plurality of second regions 23 has the same shape and spacing. As shown in FIG. 1, the mask may be formed such that each of the second regions 23 has a rectangular shape and that neighboring arrangements of the second regions have sizes and spacing different from each other.

FIGS. 2 to 4 show light-exposing procedures for fabricating unsymmetrical rectangular post-shaped photoresists according to an embodiment of the present invention.

As shown in FIG. 2, a photoresist (PR) 32 is first coated on a glass or silicone wafer substrate 31 using a spin coater. Here, the type of the photoresist 132 may vary according to the thickness thereof.

When the coating process has been completed, the coated substrate 31 is subjected to soft baking in an oven. At this time, the baking condition is preferably about 2 to 30 minutes at 70 to 120° C.

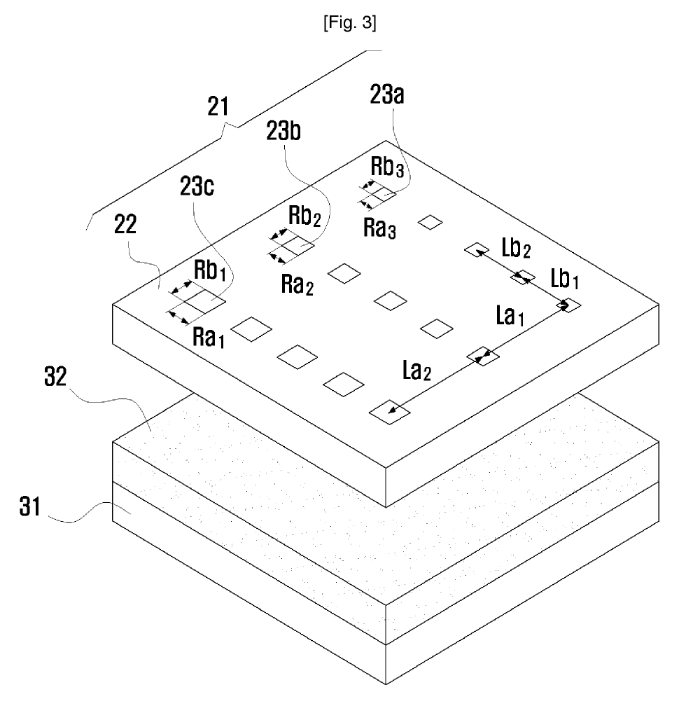

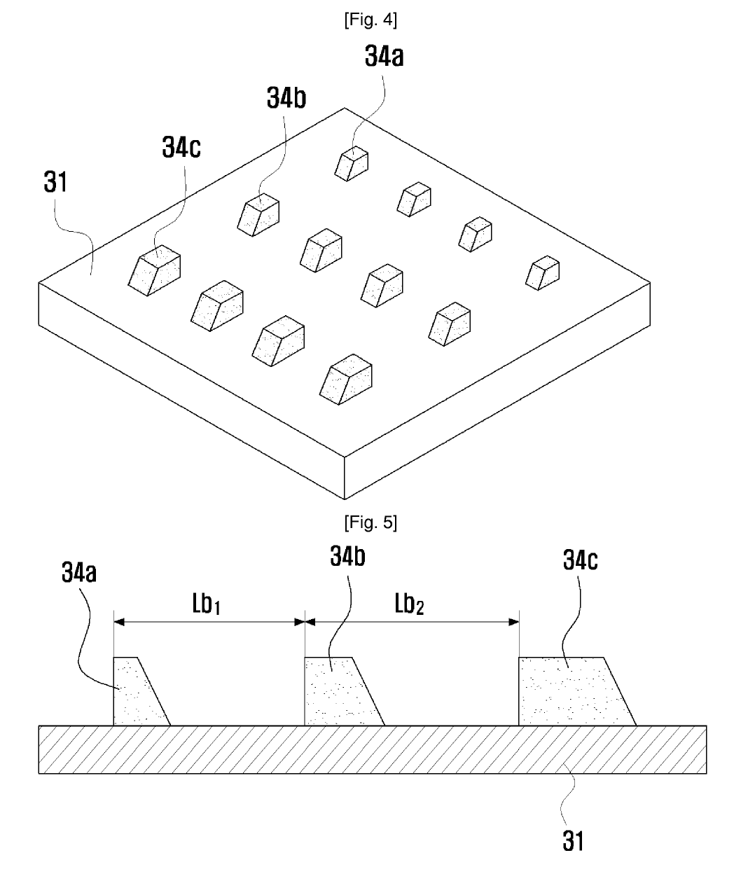

After the soft baking has been completed, as shown in FIG. 3, the mask 21 is aligned on the PR-coated substrate 31 using an alignment key. To form an unsymmetrical rectangular post as shown in FIG. 4, vertical light-exposing and slant light-exposing processes are performed for predetermined periods of time.

At this time, the mask 21 used for a light-exposing process is a mask having arrangements of the rectangular second regions 23 with different sizes and directions. In FIG. 3, Ra₁, Ra₂ and Ra₃ designate the widths of the second regions 23a, 23b and 23c in a vertical direction, and Rb₁, Rb₂ and Rb₃ designate the widths of the second regions 23a, 23b and 23c in a horizontal direction, respectively. In addition, La₁ and La₂ designate the spacing between the second regions 23 in a vertical direction, and Lb₁ and Lb₂ designate the spacing between the second regions 23 in a horizontal direction.

As shown in this figure, the widths Ra₁, Ra₂ and Ra₃, and Rb₁, Rb₂ and Rb₃ may be determined differently from one another, and the spacing of La₁ and La₂, and Lb₁ and Lb₂ may also be determined differently from each other.

After the light-exposing process has been completed, a developing process is carried out. The developing process is performed through dipping in a developing solution at room temperature.

As the results of the light-exposing process, as shown in FIG. 4, the photoresist 32 of the first region 22 through which the light has been transmitted by means of slant light exposure is melted down and disappears. The PR 32 of the second regions 23a, 23b and 23c, which have not been exposed to the light, remains as it is. Consequently, only the PRs 34 of the second regions 23 remain on the substrate 31. At this time, the photoresists 34 are formed to have the same rectangular shapes as the second regions 23 and, through the slant light exposure, to have rectangular post shapes with inclination surfaces such that the rectangular posts have larger widths at the bottoms thereof.

At this time, the PRs 34 may be fabricated in various unsymmetrical rectangular post shapes depending on changes in radiation angles and directions in the slant light exposure.

Since the unsymmetrical rectangular post-shaped photoresists 34 formed through the light-exposing process conform to the patterns of the second regions 23a, 23b and 23c in the mask 21, the unsymmetrical rectangular post-shaped PR 34a, 34b and 34c with different sizes and spacing are formed.

FIG. 5 is a sectional view of the light-exposed substrate taken in a direction of long sides of the unsymmetrical rectangular post-shaped photoresists 34a, 34b and 34c, and

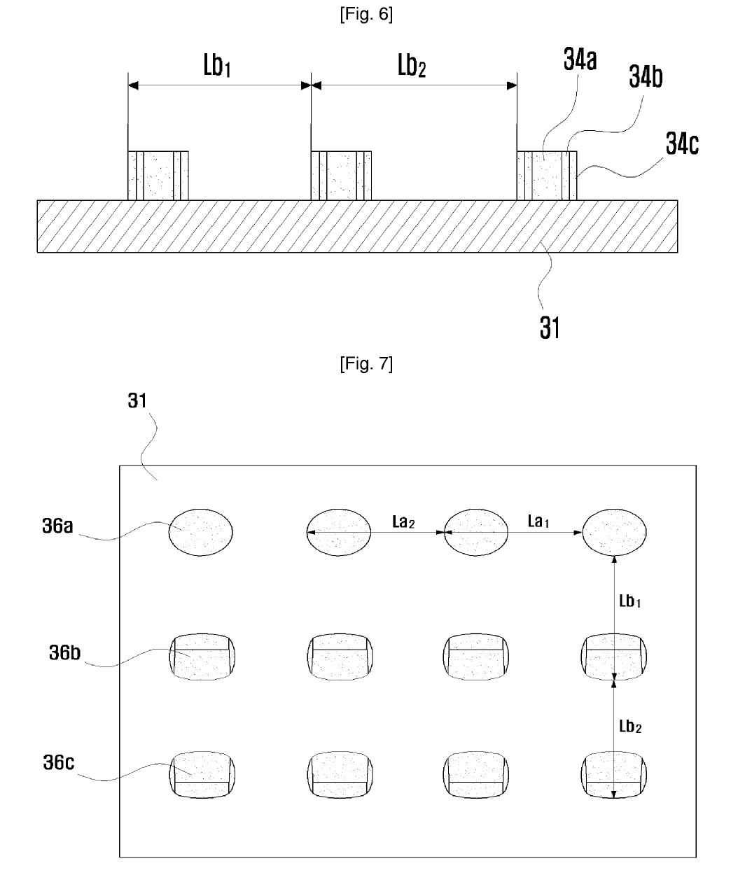

FIG. 6 is a sectional view of the light-exposed substrate taken in a direction of short sides of the unsymmetrical rectangular post-shaped photoresists 34a, 34b and 34c. As shown in these figures, the unsymmetrical rectangular post-shaped photoresists 34a, 34b and 34c may be fabricated with the same height but different sizes. Further, the spacing La and Lb between the unsymmetrical rectangular post-shaped photoresists 34a, 34b and 34c may be different depending on the direction thereof.

After the completion of the developing process, a reflow process is performed using a hot plate apparatus to allow the unsymmetrical rectangular post-shaped photoresists 34a, 34b and 34c to be curved.

Here, in the reflow process, the photoresists (PRs) 34a, 34b and 34c are heated so that the photoresists (PRs) can be melted down. At this time, the reflow condition may vary with a shape to be manufactured, for example, preferably a few minutes at 100 to 200° C.

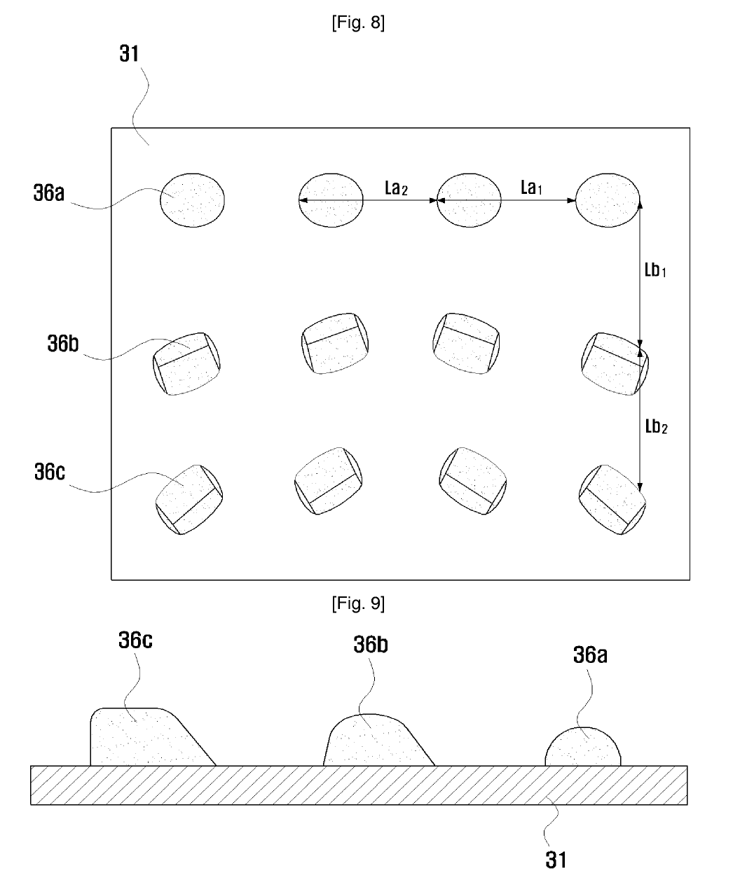

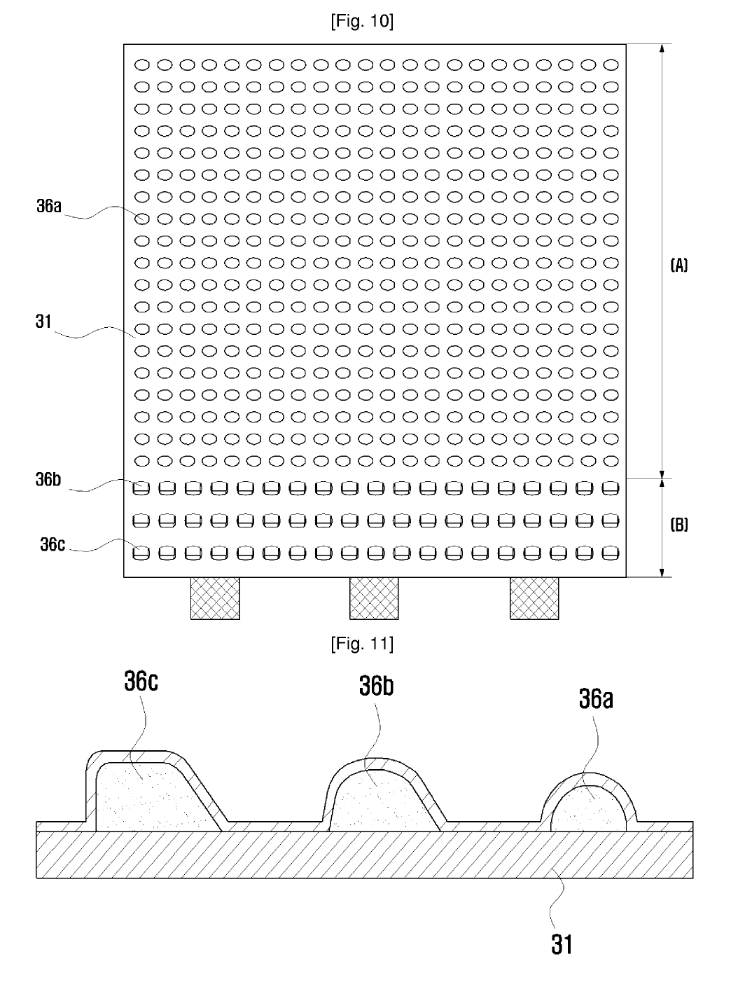

FIG. 7 is a plan view showing the state of the PRs arranged in a straight line after the reflow process according to the present invention, FIG. 8 is a plan view showing the state of the PRs arranged while angles are changed after the reflow process according to the present invention, and FIG. 9 is a sectional view showing the state of the PRs after the reflow process according to the present invention. FIG. 10 is a plan view showing a light diffusion portion B comprising trapezoidal microlenses in the vicinity of a light input section and a light guiding portion A comprising hemispherical microlenses at a predetermined distance from the light input section.

As shown in these figures, the unsymmetrical rectangular post-shaped photoresists 34a, 34b and 34c are formed through the reflow process into the trapezoidal and hemispherical microlenses constituting a hybrid microlens pattern 36.

The hybrid microlens pattern 36 manufactured as described above is determined on the basis of the size of the mask 21, slant light exposure angle and reflow time, and various forms of hybrid microlens patterns 36 may be manufactured through the reflow process.

Further, it can be seen from FIGS. 7 to 8 that the arrangements of the microlenses according to the present invention may be implemented in various forms.

According to the present invention described above, the hybrid microlens pattern 36 can be manufactured in a desired form through the process of controlling the shapes, sizes and arrangements of the second regions 23a, 23b and 23c in the mask 21, the process of controlling the angle and direction of slant light exposure, and the process of controlling the temperature and time in the reflow process. Moreover, the present invention has an advantage in that optical design can be easily made in a desired form.

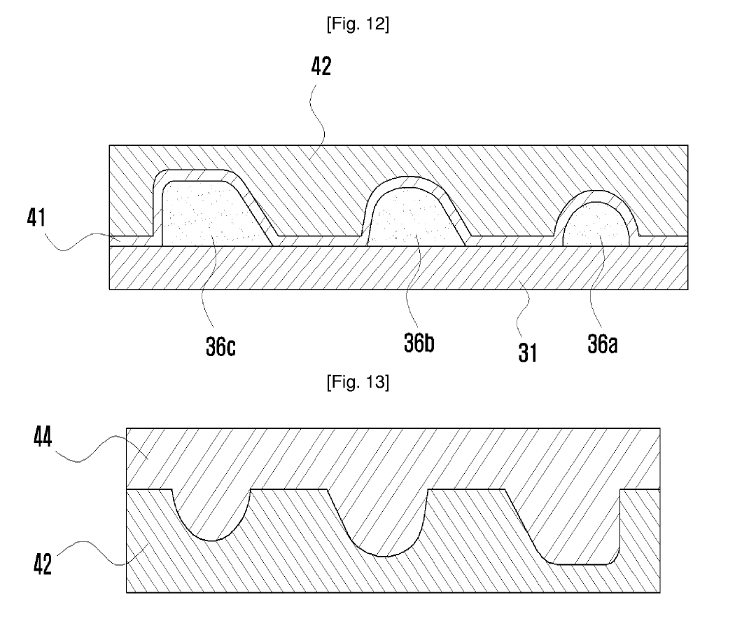

FIGS. 11 and 12 show a process of fabricating a depressed stamper according to an embodiment of the present invention.

As shown in these figures, a metallic thin film 41 is coated on the substrate 31 having the plurality of hybrid microlens patterns 36 (36a, 36b and 36c) formed thereon.

At this time, the coating of the metallic thin film 41 is typically chromium coating, and gold may be additionally coated thereon.

After the coating of the metallic thin film 41 has been completed, the substrate 31 is placed on a plating apparatus and plated with nickel through an electroplating process, as shown in FIG. 12. At this time, a supplied electric current is a few amperes depending on each step. The plating thickness is 400 to 450 [symbol] (on the basis of a 4-inch wafer), and a nickel-plated portion constitutes a stamper 42.

When the stamper 42 has been made through the nickel electroplating, the stamper 42 is separated from the substrate 31. Here, the hybrid microlens pattern 36 is transferred on the separated stamper 42 in a depressed fashion. That is, the stamper 42 (hereinafter, referred to as a “depressed stamper”) has a hybrid microlens pattern 36 formed in a depressed fashion. When the depressed stamper 42 with the hybrid microlens pattern 36 in the depressed fashion is fabricated, the depressed stamper 42 can be used as a mold to form a light guiding plate or a microlens array with a hybrid microlens array pattern in a raised fashion.

In addition, the depressed stamper 42 may be used to form another raised stamper for use in fabricating a light guiding plate with a hybrid microlens array pattern in a depressed fashion.

FIG. 13 is a schematic view showing a process of fabricating a raised stamper according to an embodiment of the present invention. As shown in this figure, nickel is newly electroplated on the hybrid microlens array pattern with unsymmetrical curvatures in the depressed stamper 42.

Through the plating process, a new nickel-plated portion 44 is formed. The nickel-plated portion 44 can be separated from the depressed stamper 42.

The new nickel-plated portion 44 separated from the depressed stamper 42 constitutes a new raised stamper 44 on which the pattern in the depressed stamper 42 is transferred.

That is, although the hybrid microlens array pattern is formed in a raised fashion, a groove is formed in a depressed fashion between the hybrid microlenses.

Thus, the raised stamper 44 can be used as a mold to form a light guiding plate (not shown) with a hybrid microlens array pattern in a depressed fashion.

In the present invention described above, as for the method for manufacturing a three-dimensional hybrid microlens, the hybrid microlens is manufactured through a semiconductor reflow process rather than machining.

To this end, in the present invention, photoresist materials are formed into unsymmetrical rectangular posts through one-time vertical light exposure and one-time slant light exposure, and the unsymmetrical rectangular posts are manufactured into a hybrid microlens pattern, including trapezoidal microlenses for reflecting and refracting light or hemispherical microlenses for scattering and diffusing light, by means of heat treatment using the reflow property of the photoresist materials. Thus, with the use of the hybrid microlens pattern, it is possible to manufacture a light guiding plate with hybrid microlenses.

Although the technical spirit of the present invention has been described with reference to the accompanying drawings, the description does not limit the present invention but merely explains the preferred embodiments of the present invention. Further, it will be understood by those skilled in the art that various changes and modifications can be made thereto without departing from the technical spirit and scope of the present invention.

1. A method for manufacturing hybrid microlenses of a light guiding plate using a semiconductor reflow process, the method comprising:
a first step of aligning a mask on a substrate coated with a photoresist, the mask being formed with a first region through which light can be transmitted and a plurality of second regions through which light cannot be transmitted, the second regions having different sizes and shapes to form hybrid arrays;
a second step of performing slant light exposure and vertical light exposure at least once in such a manner that light radiated from the top to the bottom of the second regions forming the hybrid arrays has an unsymmetrical inclination angle in at least one direction;
a third step of developing the slant light-exposed substrate to obtain hybrid photoresist posts with various sizes and shapes;
a fourth step of performing a reflow process to allow the hybrid photoresist posts to be curved so that a hybrid microlens pattern can be obtained;
a fifth step of fabricating a depressed stamper with the hybrid microlens pattern engraved in a depressed fashion therein; and
a sixth step of forming a light guiding plate by using the depressed stamper as a mold so that the hybrid microlens pattern can be formed in a raised pattern in the light guiding plate.

2. The method as claimed in claim 1, wherein the mask comprises a film mask or a chromium mask.

3. The method as claimed in claim 1, wherein the second regions of the mask are arranged on extension lines in one direction such that the hybrid arrays comprise the respective second regions with different sizes and shapes, neighboring hybrid arrays are spaced apart by a proper distance from each other, and the respective second regions forming the hybrid arrays are arranged with different spacing.

4. The method as claimed in claim 1, wherein each of the second regions of the mask is formed to take the shape of a rectangle.

5. The method as claimed in claim 1, wherein the fourth step performs the reflow process until the hybrid photoresist posts in the form of unsymmetrical slant posts form a hybrid microlens pattern with unsymmetrical rectangular post shapes at the tops thereof, or a hybrid microlens pattern with hemispherical shapes at the tops thereof.

6. The method as claimed in claim 1, wherein the fifth step comprises the steps of:
coating a metallic thin film on the substrate formed with the hybrid microlens pattern; and
electroplating the metallic thin film with nickel, and separating only a nickel-plated portion from the substrate to form the stamper.

7. The method as claimed in claim 6, wherein the coating of the metallic thin film comprises chromium coating.

8. The method as claimed in claim 7, wherein the coating of the metallic thin film further comprises additional coating of gold after the chromium coating.

9. The method as claimed in claim 1, further comprising the steps of:
fabricating a raised stamper using the depressed stamper as a master such that the hybrid microlens pattern of the depressed stamper is engraved in the raised stamper in a raised fashion; and
forming a light guiding plate using the raised stamper as a mold such that the hybrid microlens pattern is formed in the light guiding plate in a depressed fashion.

10. The method as claimed in claim 9, wherein the raised stamper is fabricated by performing nickel-plating on the hybrid microlens array pattern of the depressed stamper, and separating a nickel-plated portion from the depressed stamper.

11. A light guiding plate with a plurality of hybrid microlenses, wherein the plurality of microlenses with different sizes and shapes are arranged on extension lines in one direction on the light guiding plate, the respective microlenses with different sizes and shapes form a plurality of hybrid microlens arrays, and the microlenses forming the respective arrays are arranged with different spacing.

12. The light guiding plate as claimed in claim 11, wherein a part of the plurality of hybrid microlenses formed on the light guiding plate has a different size or is arranged in a different direction.

13. The light guiding plate as claimed in claim 11, wherein the light guiding plate comprises a light diffusion portion for diffusing light from a light input section by means of microlenses, and a light guiding portion for performing diffuse reflection of light on microlenses to exhibit uniform luminance.
